(19) United States
(12) Patent Application Publication
(10) Pub. No.: US 2025/0382698 A1
(43) Pub. Date: Dec. 18, 2025

(54) FILM-FORMING METHOD AND FILM-FORMING APPARATUS

(71) Applicant: Tokyo Electron Limited, Tokyo (JP)

(72) Inventors: Keiji TABUKI, Yamanashi (JP); Ken OKOSHI, Yamanashi (JP); Jun OGAWA, Yamanashi (JP)

(21) Appl. No.: 19/209,012

(22) Filed: May 15, 2025

(30) Foreign Application Priority Data
Jun. 13, 2024 (JP) 2024-096122

(51) Int. Cl. C23C 16/04; C23C 16/34; C23C 16/455; C23C 16/52

(52) U.S. Cl. CPC C23C 16/045; C23C 16/042; C23C 16/345; C23C 16/45527; C23C 16/45553; C23C 16/52

(57) ABSTRACT

A film-forming method includes (a) providing a substrate including a recess; (b) supplying aminosilane to the substrate, and forming an inhibition layer over a surface of the recess; (c) forming a silicon nitride film over the surface of the recess by performing a cycle a first number of times, the cycle including supplying a silicon raw material to the substrate, and supplying a nitriding agent to the substrate at a timing different from the supply of the silicon raw material to the substrate; and (d) repeatedly performing (b) and (c) in order of (b) and (c).

### CROSS-REFERENCE TO RELATED APPLICATIONS

This application is based upon and claims priority to Japanese Patent Application No. 2024-096122, filed on Jun. 13, 2024, the entire contents of which are incorporated herein by reference.

### BACKGROUND

### 1. Field of the Invention

The present disclosure relates to a film-forming method and a film-forming apparatus.

### 2. Description of the Related Art

A technique of embedding a silicon nitride film into a recess formed in a substrate is disclosed. See, for example, Japanese Laid-Open Patent Application Publication No. 2017-139306.

### SUMMARY

A film-forming method according to an aspect of the present disclosure includes: providing a substrate including a recess; supplying aminosilane to the substrate, and forming an inhibition layer over a surface of the recess; forming a silicon nitride film over the surface of the recess by performing a cycle a first number of times, the cycle including supplying a silicon raw material to the substrate, and supplying a nitriding agent to the substrate at a timing different from the supply of the silicon raw material to the substrate; and repeatedly performing the formation of the inhibition layer and the formation of the silicon nitride film in order from the formation of the inhibition layer to the formation of the silicon nitride film. The first number of times is a number of times that is equal to or less than a value calculated through subtraction of a second number of incubation cycles from a first number of incubation cycles. The first number of incubation cycles is a number of incubation cycles of the silicon nitride film relative to a base in the presence of the inhibition layer over the base forming the surface of the recess. The second number of incubation cycles is a number of incubation cycles of the silicon nitride film relative to the base in the absence of the inhibition layer over the base.

### BRIEF DESCRIPTION OF THE DRAWINGS

FIG. 1 is a flowchart illustrating a film-forming method according to an embodiment of the present disclosure;

FIG. 2 is a cross-sectional view (1) illustrating the film-forming method according to the embodiment;

FIG. 3 is a cross-sectional view (2) illustrating the film-forming method according to the embodiment;

FIG. 4 is a cross-sectional view (3) illustrating the film-forming method according to the embodiment;

FIG. 5 is a cross-sectional view (4) illustrating the film-forming method according to the embodiment;

FIG. 6 is a flowchart illustrating an example of the inhibition layer-forming step illustrated in FIG. 1;

FIG. 7 is a flowchart illustrating an example of the film-forming step illustrated in FIG. 1;

FIG. 8 is a graph illustrating a relationship between the number of ALD cycles and the thickness of a silicon nitride film;

FIG. 9 is a vertical cross-sectional view illustrating a film-forming apparatus according to an embodiment of the present disclosure; and

FIG. 10 is a horizontal cross-sectional view illustrating the film-forming apparatus according to the embodiment.

### DETAILED DESCRIPTION OF THE DISCLOSURE

The present disclosure provides a technique of improving embedding properties when embedding a film into a recess.

Hereinafter, non-limiting exemplary embodiments of the present disclosure will be described with reference to the attached drawings. In the drawings, the same or corresponding members or parts will be denoted by the same or corresponding reference symbols, and thus duplicate description thereof will be omitted.

[Film-Forming Method]

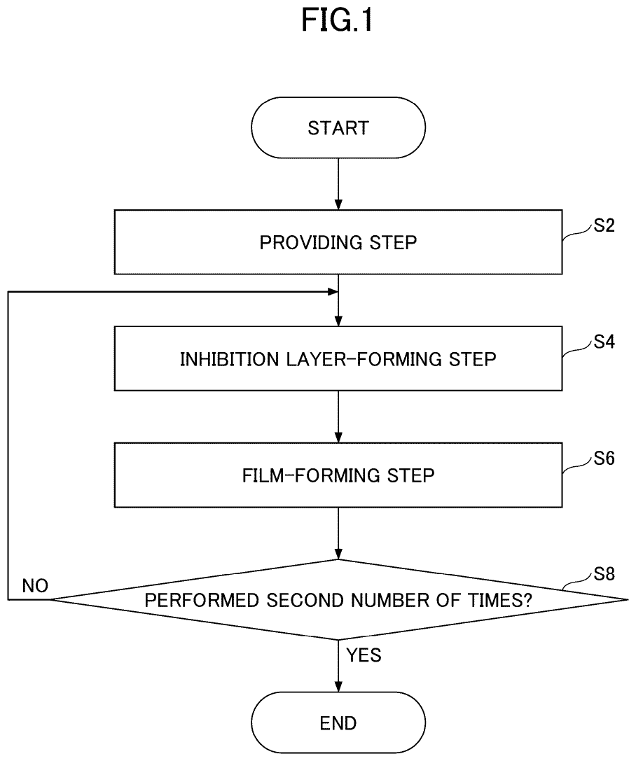

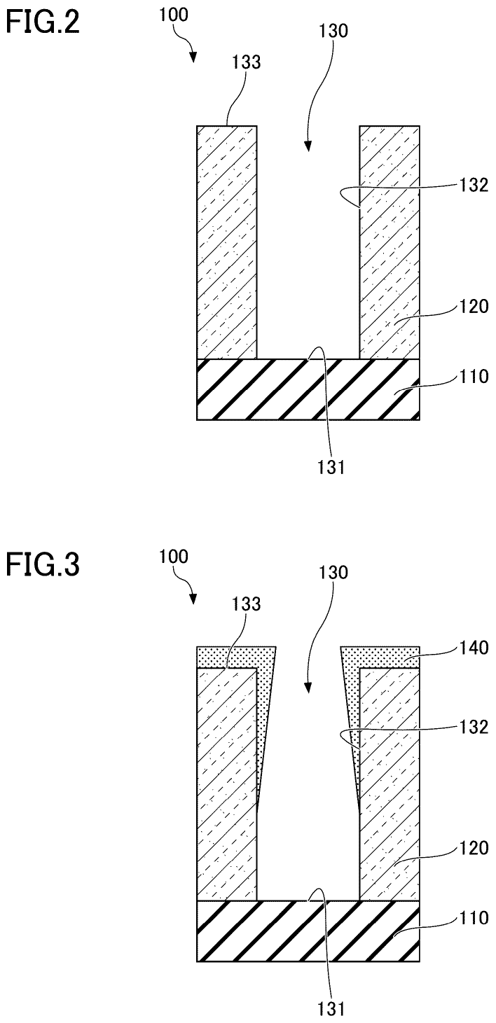

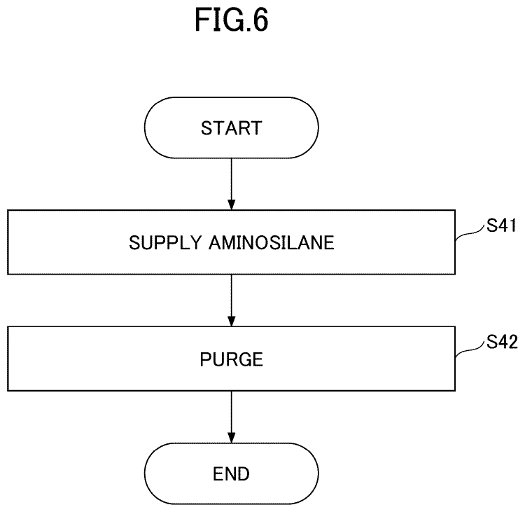

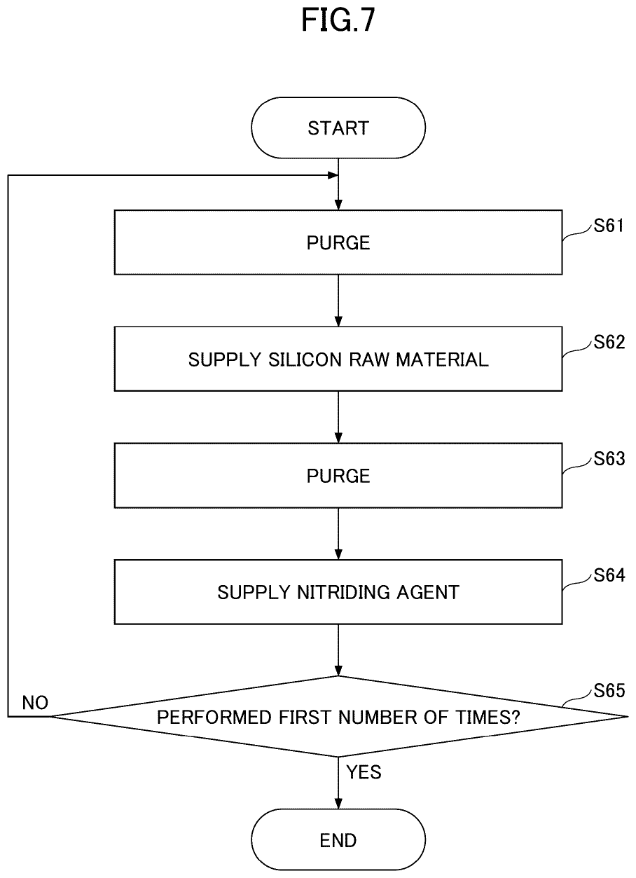

A film-forming method according to an embodiment of the present disclosure will be described with reference to FIGS. 1 to 8. FIG. 1 is a flowchart illustrating the film-forming method according to the embodiment. FIGS. 2 to 5 are cross-sectional views illustrating the film-forming method according to the embodiment. FIG. 6 is a flowchart illustrating an example of an inhibition layer-forming step S4 illustrated in FIG. 1. FIG. 7 is a flowchart illustrating an example of a film-forming step S6 illustrated in FIG. 1.

As illustrated in FIG. 1, the film-forming method according to the embodiment includes a providing step S2, the inhibition layer-forming step S4, the film-forming step S6, and a determination step S8.

The providing step S2 includes providing a substrate 100 as illustrated in FIG. 2. The substrate 100 includes a silicon nitride film 110 and a silicon film 120. The silicon nitride film 110 has a flat top surface. The silicon film 120 is provided over the top surface of the silicon nitride film 110. The silicon film 120 has a projecting shape. The silicon film 120 is, for example, an amorphous silicon film. The silicon nitride film 110 and the silicon film 120 form a recess 130. The recess 130 has a bottom surface 131, a side surface 132, and a top surface 133. The silicon nitride film 110 forms the bottom surface 131. The silicon film 120 forms the side surface 132 and the top surface 133.

The inhibition layer-forming step S4 is performed after the providing step S2. As illustrated in FIG. 3, the inhibition layer-forming step S4 includes forming an inhibition layer 140 over the side surface 132 of the recess 130 such that the thickness of the inhibition layer 140 at an upper portion in a depth direction is larger than the thickness of the inhibition layer 140 at a lower portion in the depth direction. The inhibition layer 140 is formed of aminosilane. The aminosilane has a property to inhibit formation of a silicon nitride film 150. The aminosilane is, for example, TMSDMA ((trimethylsilyl)dimethylamine). The inhibition layer-forming step S4 may include not forming the inhibition layer 140 over the bottom surface 131 of the recess 130. In this case, the formation of the silicon nitride film 150 over the bottom surface 131 can be promoted in the film-forming step S6. The inhibition layer-forming step S4 may include forming the inhibition layer 140 over the top surface 133 of the recess 130. In this case, the formation of the silicon nitride film 150 over the top surface 133 can be inhibited in the film-forming step S6. The inhibition layer-forming step S4 includes, for example, steps S41 and S42 illustrated in FIG. 6.

Step S41 includes supplying aminosilane to the substrate 100. In step S41, process conditions for supplying aminosilane to the substrate 100 are adjusted such that aminosilane is adsorbed onto the side surface 132 of the recess 130 in an amount that is larger at the upper portion in the depth direction than at the lower portion in the depth direction. The process conditions include a substrate temperature, a processing pressure, a flow rate of aminosilane to be supplied, and the like. In step S41, the substrate temperature is, for example, 300° C. or more and 630° C. or less, and the processing pressure is, for example, 0.001 Torr or more and 10 Torr or less.

Step S42 is performed after step S41. Step $42 includes purging the aminosilane remaining in the process chamber in which the substrate 100 is housed.

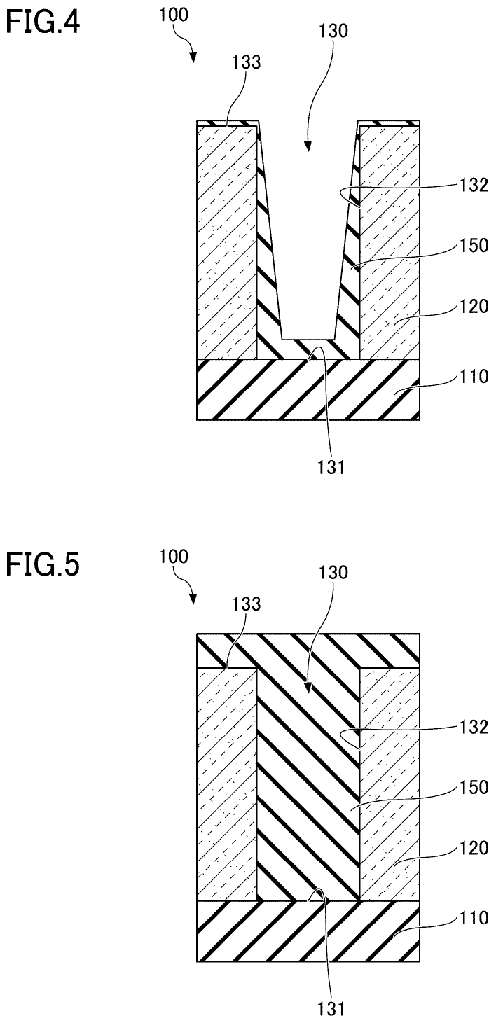

The film-forming step S6 is performed after the inhibition layer-forming step S4. The film-forming step S6 includes forming the silicon nitride film 150 through atomic layer deposition (ALD). In the film-forming step S6, as illustrated in FIG. 4, the silicon nitride film 150 is formed to be thicker at the lower portion of the recess 130 where the inhibition layer 140 is thinner. The film-forming step S6 includes, for example, forming the silicon nitride film 150 in the recess 130 by performing an ALD cycle a first number of times, the ALD cycle including supplying a silicon raw material to the substrate 100, and supplying a nitriding agent to the substrate 100 at a timing different from the supply of the silicon raw material to the substrate 100. The silicon raw material is, for example, dichlorosilane (DCS). The nitriding agent is, for example, ammonia (NH₃). The film-forming step S6 is, for example, a thermal process that does not use a plasma. In this case, generation of impurities derived from aminosilane can be reduced. The film-forming step S6 may be a plasma process that uses a plasma. The film-forming step S6 includes, for example, steps S61 to S65 illustrated in FIG. 7.

Step S61 includes purging the nitriding agent remaining in the process chamber in which the substrate 100 is housed.

Step S62 is performed after step S61. Step S62 includes supplying a silicon raw material to the substrate 100. The silicon raw material does not readily adsorb onto the surface where the thickness of the inhibition layer 140 is larger. Therefore, the silicon raw material is adsorbed in a larger thickness at the lower portion of the recess 130, where the thickness of the inhibition layer 140 is smaller. In step S62, the substrate temperature is, for example, 300° C. or more and 630° C. or less.

Step S63 is performed after step S62. Step S63 includes purging the silicon raw material remaining in the process chamber in which the substrate 100 is housed.

Step S64 is performed after step S63. Step S64 includes supplying a nitriding agent to the substrate 100, and nitriding the silicon raw material adsorbed onto the surface of the recess 130.

Step S65 is performed after step S64. Step S65 includes determining whether or not a cycle of steps S61 to S64 has been performed the first number of times. If the cycle of steps S61 to S64 has not been performed the first number of times (NO in step S65), the cycle of steps S61 to S64 is performed again. If the cycle of steps S61 to S64 has been performed the first number of times (YES in step S65), the film-forming step S6 is ended. By repeatedly performing a cycle of steps $61 to S65 until the cycle of steps S61 to S64 is performed the first number of times, the silicon nitride film 150 having a substantially V shape can be formed in the recess 130 as illustrated in FIG. 4.

The first number of times is equal to or less than a value calculated through subtraction of a second number of incubation cycles from a first number of incubation cycles. The first number of incubation cycles is the number of incubation cycles in the presence of the inhibition layer 140 over the base forming the surface of the recess 130. The second number of incubation cycles is the number of incubation cycles in the absence of the inhibition layer 140 over the base forming the surface of the recess 130. The number of incubation cycles is the number of ALD cycles (hereinafter referred to as an “ALD cycle number”) required from the start of the repetition of the ALD cycle including supplying the silicon raw material and supplying the nitriding agent at a timing different from the supply of the silicon raw material until the start of the formation of the silicon nitride film over the base. The surface of the recess 130 is, for example, the side surface 132 of the recess 130, and the base is the silicon film 120.

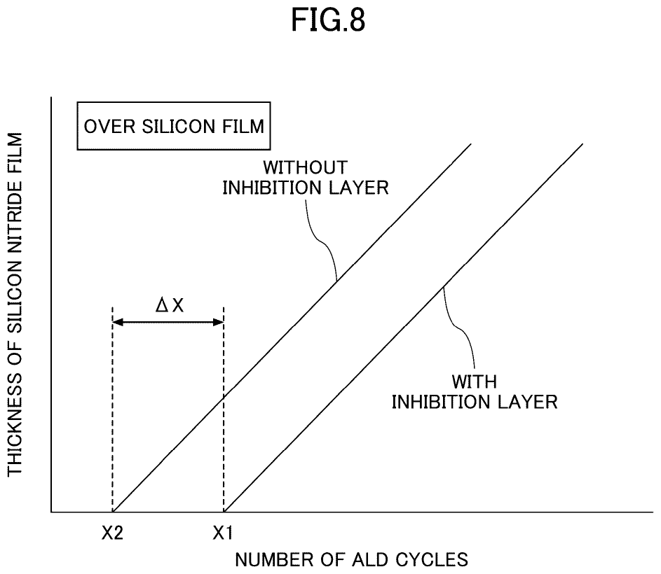

FIG. 8 is a graph illustrating a relationship between the ALD cycle number and the thickness of the silicon nitride film. In FIG. 8, the horizontal axis indicates the ALD cycle number, and the vertical axis indicates the thickness of the silicon nitride film formed over the silicon film. In the example illustrated in FIG. 8, X1 is the first number of incubation cycles, and X2 is the second number of incubation cycles. The first number of times is the number of times equal to or less than AX. AX is calculated according to the formula ΔX=X1−X2. AX is, for example, within the range of 10 times to 20 times. The first number of times is, for example, 2 times to 10 times.

The determination step S8 is performed after the film-forming step S6. The determination step S8 includes determining whether or not a cycle of the inhibition layer-forming step S4 and the film-forming step S6 has been performed the second number of times. If the cycle of steps S4 and S6 has not been performed the second number of times (NO in the determination step S8), the cycle of steps S4 and S6 is performed again. If the cycle of steps S4 and S6 has been performed the second number of times (YES in the determination step S8), the process is ended. In this manner, the inhibition layer-forming step S4 and the film-forming step S6 are repeatedly performed in order from S4 to S6 until the inhibition layer-forming step S4 and the film-forming step S6 are performed the second number of times. The second number of times is the number of times required to embed the silicon nitride film 150 into the recess 130, as illustrated in FIG. 5.

As described above, according to the film-forming method according to the embodiment, the inhibition layer-forming step S4 is performed once every time the cycle including supplying the silicon raw material and supplying the nitriding agent at a timing different from the supply of the silicon raw material is performed the first number of times. The first number of times is equal to or less than the value calculated through subtraction of the second number of incubation cycles from the first number of incubation cycles. In this case, in the inhibition layer-forming step S4, the inhibition layer 140 can be formed over the side surface 132 of the recess 130 such that the thickness of the inhibition layer 140 at the upper portion in the depth direction is larger than the thickness of the inhibition layer 140 at the lower portion in the depth direction. Therefore, in the film-forming step S6, the silicon nitride film 150 can be formed over the side surface 132 of the recess 130 such that the thickness of the silicon nitride film 150 at the lower portion in the depth direction is larger than the thickness of the silicon nitride film 150 at the upper portion in the depth direction. As a result, the silicon nitride film 150 is formed from the bottom surface 131 of the recess 130 toward the top surface 133 of the recess 130, and thus it is possible to reduce formation of voids, seams, and the like in the recess 130. In other words, it is possible to improve embedding properties when embedding the silicon nitride film 150 into the recess 130.

In the above embodiment, when the inhibition layer-forming step S4 and the film-forming step S6 are repeatedly performed in order from S4 to S6 the second number of times, the process conditions for the inhibition layer-forming step S4 may be changed partway of the repetition. In this case, it is possible to adjust a position in the recess 130 where aminosilane is to be adsorbed. The process conditions include a flow rate of aminosilane to be supplied, a processing pressure, and the like. From partway of the repetition, the film-forming step S6 alone may be performed without performing the inhibition layer-forming step S4. In this case, it is possible to reduce the time required to embed the silicon nitride film 150 into the recess 130 of the silicon nitride film 150.

### [Film-Forming Apparatus]

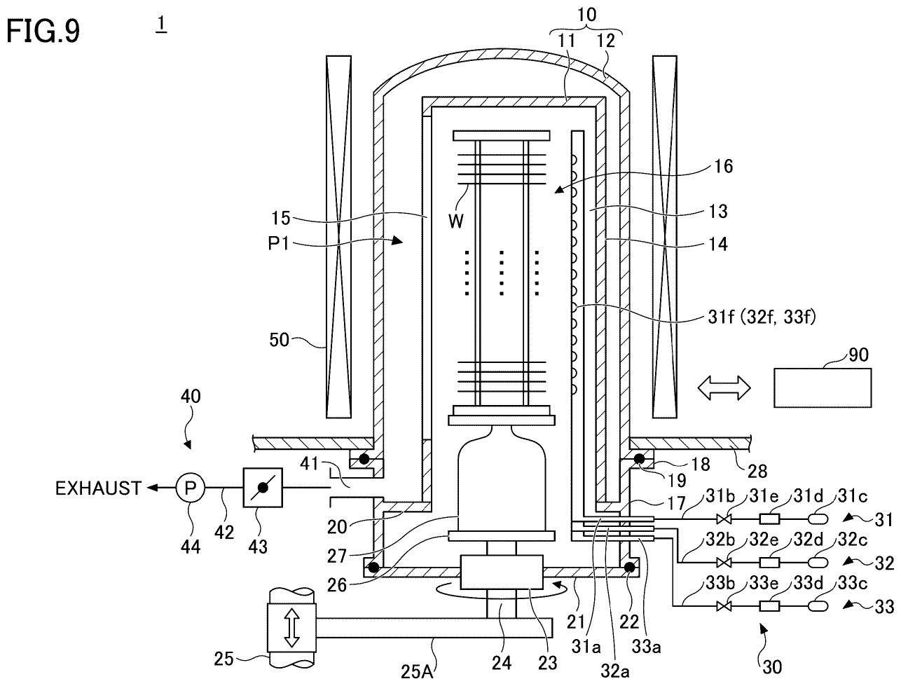

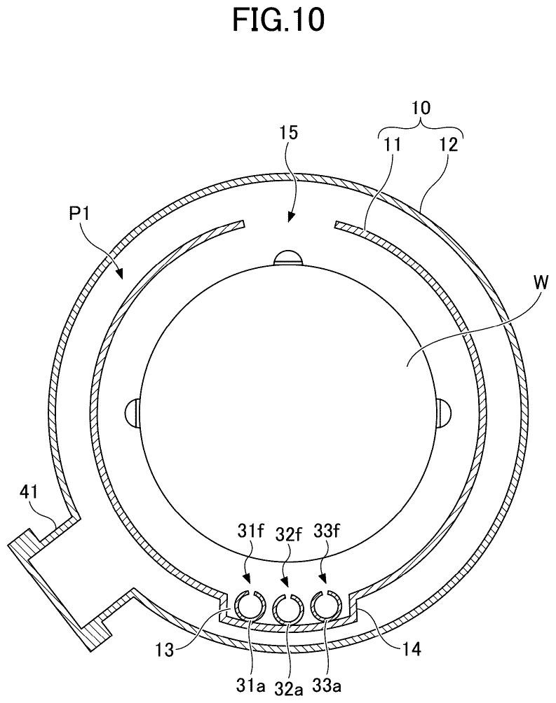

A film-forming apparatus 1 according to an embodiment of the present disclosure will be described with reference to FIGS. 9 and 10. FIG. 9 is a vertical cross-sectional view illustrating the film-forming apparatus 1 according to the embodiment. FIG. 10 is a horizontal cross-sectional view illustrating the film-forming apparatus 1 according to the embodiment.

The film-forming apparatus 1 is a batch-type apparatus configured to process a plurality of substrates W at one time. The substrates W are, for example, semiconductor wafers. The film-forming apparatus 1 includes a process chamber 10, a gas supply 30, a gas exhauster 40, a heater 50, and a controller 90.

The internal pressure of the process chamber 10 can be reduced. The process chamber 10 is configured to house the substrates W. The process chamber 10 includes an inner tube 11 and an outer tube 12. The inner tube 11 has a cylindrical shape having a ceiling and an opened bottom end. The outer tube 12 has a cylindrical shape having a ceiling and an opened bottom end, and covers the outside of the inner tube 11. The inner tube 11 and the outer tube 12 are formed of a heat-resistant material, such as quartz or the like. The inner tube 11 and the outer tube 12 have a double-tube structure in which they are arranged coaxially.

The side wall of the inner tube 11 is provided with a housing 13 configured to house a gas supply tube along the longitudinal direction (vertical direction) of the inner tube 11. For example, a part of the side wall of the inner tube 11 is projected outward to form a projecting portion 14, and the interior of the projecting portion 14 is formed as the housing 13.

The side wall of the inner tube 11 is provided with a rectangular opening 15 that is along the longitudinal direction of the inner tube 11. The opening 15 faces the housing 13.

The opening 15 is a gas exhaust opening formed to allow the gas in the inner tube 11 to be exhausted. The length of the opening 15 is the same as the length of a boat 16, or is longer than the length of the boat 16, specifically, the opening 15 is formed to vertically extend beyond both vertical ends of the boat 16.

The bottom end of the process chamber 10 is supported by a cylindrical manifold 17. The manifold 17 is formed, for example, of stainless steel. A flange 18 is formed at the top end of the manifold 17. The flange 18 supports the bottom end of the outer tube 12. A sealing 19, such as an O-ring or the like, is provided between the flange 18 and the bottom end of the outer tube 12. Thus, the interior of the outer tube 12 is maintained to be airtight.

The inner wall of the upper portion of the manifold 17 is provided with an annular support 20. The support 20 supports the bottom end of the inner tube 11. A cover 21 is airtightly attached to an opening at the bottom end of the manifold 17 via a sealing 22, such as an O-ring or the like. Thus, the opening at the bottom end of the process chamber 10, i.e., the opening of the manifold 17, is airtightly closed. The cover 21 is formed, for example, of stainless steel.

The center portion of the cover 21 is provided, via a magnetic fluid seal 23, with a rotating shaft 24 that penetrates through the cover 21. The lower portion of the rotating shaft 24 is rotatably supported by an arm 25A of a raising and lowering mechanism 25 that is implemented by a boat elevator.

The top end of the rotating shaft 24 is provided with a rotating plate 26. A boat 16 configured to hold the substrates W is placed over the rotating plate 26 via a temperature-retaining stage 27 formed of quartz. The boat 16 is rotated by rotating the rotating shaft 24. The boat 16 is vertically moved integrally with the cover 21 by raising and lowering the raising and lowering mechanism 25. Thus, the boat 16 is inserted into and removed from the process chamber 10. The boat 16 can be housed in the process chamber 10. The boat 16 holds the substrates W (e.g., 50 to 150 substrates) at intervals in a vertically stacked manner. The boat 16 substantially horizontally holds the substrates W at intervals in the vertical direction.

The gas supply 30 is configured to introduce various process gases into the inner tube 11. The gas supply 30 includes a TMSDMA supply 31, a DCS supply 32, and an ammonia supply 33.

The TMSDMA supply 31 includes a gas supply tube 31a in the process chamber 10, and a supply path 31b outside the process chamber 10. The supply path 31b includes a TMSDMA source 31c, a mass flow controller 31d, and a valve 31e in order from upstream to downstream in the gas flow direction. Thus, the supply timing of the TMSDMA in the TMSDMA source 31c is controlled by the valve 31e, and the flow rate of the TMSDMA is adjusted to a predetermined flow rate by the mass flow controller 31d. The TMSDMA flows into the gas supply tube 31a from the supply path 31b, and is discharged into the process chamber 10 from the gas supply tube 31a.

The DCS supply 32 includes a gas supply tube 32a in the process chamber 10, and a supply path 32b outside the process chamber 10. The supply path 32b includes a DCS source 32c, a mass flow controller 32d, and a valve 32e in order from upstream to downstream in the gas flow direction. Thus, the supply timing of the DCS in the DCS source 32c is controlled by the valve 32e, and the flow rate of the DCS is adjusted to a predetermined flow rate by the mass flow controller 32d. The DCS flows into the gas supply tube 32a from the supply path 32b, and is discharged into the process chamber 10 from the gas supply tube 32a.

The ammonia supply 33 includes a gas supply tube 33a in the process chamber 10, and a supply path 33b outside the process chamber 10. The supply path 33b includes an ammonia source 33c, a mass flow controller 33d, and a valve 33e in order from upstream to downstream in the gas flow direction. Thus, the supply timing of the ammonia in the ammonia source 33c is controlled by the valve 33e, and the flow rate of the ammonia is adjusted to a predetermined flow rate by the mass flow controller 33d. The ammonia flows into the gas supply tube 33a from the supply path 33b, and is discharged into the process chamber 10 from the gas supply tube 33a.

The gas supply tubes 31a, 32a, and 33a are fixed to the manifold 17. The gas supply tubes 31a, 32a, and 33a are formed, for example, of quartz. The gas supply tubes 31a, 32a, and 33a vertically extend in a straight line near the inner tube 11, and bend in an L shape in the manifold 17 and horizontally extend to penetrate through the manifold 17. The gas supply tubes 31a, 32a, and 33a are provided side by side along the circumferential direction of the inner tube 11 and are formed at the same height.

A plurality of discharge holes 31f, 32f, and 33f are provided at portions of the gas supply tubes 31a, 32a, and 33a that are positioned in the inner tube 11. The discharge holes 31f, 32f, and 33f are formed at predetermined intervals along the extending direction of the gas supply tubes 31a, 32a, and 33a. The discharge holes 31f, 32f, and 33f horizontally discharge gas toward the substrate W from the outside in the radial direction of the substrate W. The discharge holes 31f, 32f, and 33f discharge gas parallel to the main surface of the substrate W. The distance between the discharge holes is set, for example, to be equal to the distance between the substrates W held by the boat 16. The position of each discharge hole in the height direction is set, for example, at the middle position between the substrates W that are next to each other in the vertical direction. In this case, each discharge hole can efficiently supply gas to a facing surface between the substrates W next to each other.

The gas supply 30 may mix two or more types of gases together, and discharge the mixed gas from a single gas supply tube. The gas supply tubes 31a, 32a, and 33a may have different shapes and arrangements. The gas supply 30 may further include a gas supply tube configured to supply a different type of gas, e.g., an inert gas.

The gas exhauster 40 is configured to exhaust the gas that is discharged through the opening 15 from the interior of the inner tube 11 and then discharged from a gas outlet 41 through a space P1 between the inner tube 11 and the outer tube 12. The gas outlet 41 is formed at the side wall upward of the manifold 17 and above the support 20. A gas exhaust path 42 is connected to the gas outlet 41. A pressure regulating valve 43 and a vacuum pump 44 are sequentially disposed in the gas exhaust path 42 with a gap such that the internal gas of the process chamber 10 can be exhausted.

The heater 50 is provided around the outer tube 12. The heater 50 is provided, for example, over a base plate 28. The heater 50 has a cylindrical shape to cover the outer tube 12. The heater 50 includes, for example, a heat generator, and is configured to heat the substrates W in the process chamber 10.

The controller 90 is an electronic circuit, such as a central processing unit (CPU), a graphics processing unit (GPU), a field programmable gate array (FPGA), an application specific integrated circuit (ASIC), or the like. The controller 90 is configured to execute various controls described in the present specification by executing instruction codes stored in a memory or by being designed as a circuit for specific applications.

### [Driving of Film-Forming Apparatus]

How the film-forming apparatus 1 is driven when the film-forming apparatus 1 performs the film-forming method according to the embodiment will be described. The driving of the film-forming apparatus 1 described below is performed under the control of the controller 90.

First, the controller 90 performs the providing step S2. Specifically, the raising and lowering mechanism 25 transfers the boat 16, holding the plurality of substrates W, into the process chamber 10, and the cover 21 airtightly closes the opening at the lower end of the process chamber 10. Subsequently, the gas exhauster 40 reduces the internal pressure of the process chamber 10, and the heater 50 adjusts the temperature of the substrates W to a predetermined temperature (e.g., 630° C.). The substrates W may be the substrate 100 described above.

Next, the controller 90 performs the inhibition layer-forming step S4. Specifically, the gas supply 30 supplies TMSDMA into the process chamber 10, and forms the inhibition layer 140 over the side surface 132 of the recess 130 such that the thickness of the inhibition layer 140 at the upper portion in the depth direction is larger than the thickness of the inhibition layer 140 at the lower portion in the depth direction.

Next, the controller 90 performs the film-forming step S6. Specifically, the silicon nitride film 150 is formed over the recess 130 by performing a cycle the first number of times, the cycle including supplying DCS into the process chamber 10 from the gas supply 30, and supplying ammonia into the process chamber 10 from the gas supply 30 at a timing different from the supply of the DCS into the process chamber 10 from the gas supply 30. Here, the inhibition layer 140 is formed over the side surface 132 of the recess 130 such that the thickness of the inhibition layer 140 at the upper portion in the depth direction is larger than the thickness of the inhibition layer 140 at the lower portion in the depth direction. Thus, the silicon nitride film 150 can be formed over the side surface 132 of the recess 130 such that the thickness of the silicon nitride film 150 at the lower portion in the depth direction is larger than the thickness of the silicon nitride film 150 at the upper portion in the depth direction. The first number of times is, for example, 10 times.

Next, the controller 90 performs the determination step S8. Specifically, the controller 90 determines whether or not the cycle of the inhibition layer-forming step S4 and the film-forming step S6 has been performed the second number of times. If the cycle of steps S4 and S6 has not been performed the second number of times, the cycle of steps S4 and S6 is performed again. If the cycle of steps S4 and S6 has been performed the second number of times, the process is ended. In this manner, the controller 90 repeatedly performs the inhibition layer-forming step S4 and the film-forming step S6 in order from S4 to S6 until the inhibition layer-forming step S4 and the film-forming step S6 are performed the second number of times.

Next, the controller 90 increases the internal pressure of the process chamber 10 to the atmospheric pressure, and lowers the internal temperature of the process chamber 10 to a temperature at which the boat 16 can be transferred out of the process chamber 10. Then, the controller 90 controls the raising and lowering mechanism 25, thereby transferring the boat 16 out of the process chamber 10.

As described above, the film-forming method according to the embodiment can be performed by the film-forming apparatus 1.

The embodiments disclosed herein should be considered to be exemplary in all respects, not to be restrictive. Omissions, substitutions, and modifications may be made in various forms to the above-described embodiments without departing from the scope and intent of the claims recited.

In the above embodiments, the aminosilane is TMSDMA. However, the present disclosure is not limited to this. The aminosilane may be TMSDMA, DIPAS (di(isopropylamino)silane), 3DMAS (tris(dimethylamino)silane), BTBAS (bis(tert-butylamino)silane), or any combination.

In the above embodiments, the silicon raw material is DCS. However, the present disclosure is not limited to this. The silicon raw material may be a fluorine-containing silicon, such as SiF₄, SiHF₃, SiH₂F₂, SiH₃F, or the like, chlorine-containing silicon, such as SiCl₄, SiHCl₃, SiH₂Cl₂ (DCS), SiH₃Cl, Si₂Cl₆ gas, or the like, bromine-containing silicon, such as SiBr₄, SiHBr₃, SiH₂Br₂, SiH₃Br, or the like, or any combination.

In the above embodiments, the nitriding agent is ammonia. However, the present disclosure is not limited to this. The nitriding agent may be ammonia, diazene (N₂H₂), hydrazine (NH₄), monomethylhydrazine (CH₃(NH)NH₂), or any combination.

In the above embodiments, the film-forming apparatus is a batch-type apparatus configured to process a plurality of substrates at one time. The present disclosure is not limited to this. For example, the film-forming apparatus may be a single-wafer type apparatus configured to process substrates one by one. For example, the film-forming apparatus may be a semi-batch-type apparatus configured to process a plurality of substrates disposed on a rotation table by rotating the rotation table to cause each of the substrates to revolve and repeatedly pass through process gas supply regions disposed along a radius direction of the rotation table.

According to the present disclosure, it is possible to improve embedding properties when embedding a film into a recess.

What is claimed is:

1. A film-forming method, comprising:
(a) providing a substrate including a recess;
(b) supplying aminosilane to the substrate, and forming an inhibition layer over a surface of the recess;
(c) forming a silicon nitride film over the surface of the recess by performing a cycle a first number of times, the cycle including supplying a silicon raw material to the substrate, and supplying a nitriding agent to the substrate at a timing different from the supply of the silicon raw material to the substrate; and
(d) repeatedly performing (b) and (c) in order from (b) to (c), wherein
the first number of times is a number of times that is equal to or less than a value calculated through subtraction of a second number of incubation cycles from a first number of incubation cycles,
the first number of incubation cycles is a number of incubation cycles of the silicon nitride film relative to a base in a presence of the inhibition layer over the base forming the surface of the recess, and
the second number of incubation cycles is a number of incubation cycles of the silicon nitride film relative to the base in an absence of the inhibition layer over the base.

2. The film-forming method according to claim 1, wherein
the surface of the recess is a side surface of the recess.

3. The film-forming method according to claim 2, wherein
(b) includes forming the inhibition layer over the side surface of the recess such that a thickness of the inhibition layer at an upper portion in a depth direction is larger than the thickness of the inhibition layer at a lower portion in the depth direction.

4. The film-forming method according to claim 1, wherein
(d) includes changing process conditions for (b) partway of (d).

5. The film-forming method according to claim 4, wherein
the process conditions include a flow rate of the aminosilane to be supplied.

6. The film-forming method according to claim 4, wherein
the process conditions include a processing pressure.

7. The film-forming method according to claim 1, wherein
(c) is a thermal process that does not use a plasma.

8. The film-forming method according to claim 1, wherein
the base is a silicon film.

9. The film-forming method according to claim 1, wherein
the aminosilane is (trimethylsilyl)dimethylamine,
the silicon raw material is dichlorosilane, and
the nitriding agent is ammonia.

10. A film-forming apparatus, comprising:
a process chamber configured to house a substrate;
a gas supply configured to supply gas into the process chamber; and
a controller including a circuit, wherein
the circuit is configured to perform:
(a) providing the substrate including a recess;
(b) supplying aminosilane to the substrate, and forming an inhibition layer over a surface of the recess;
(c) forming a silicon nitride film over the surface of the recess by performing a cycle a first number of times, the cycle including supplying a silicon raw material to the substrate, and supplying a nitriding agent to the substrate at a timing different from the supply of the silicon raw material to the substrate; and
(d) repeatedly performing (b) and (c) in order from (b) to (c), and
the first number of times is a number of times that is equal to or less than a value calculated through subtraction of a second number of incubation cycles from a first number of incubation cycles,
the first number of incubation cycles is a number of incubation cycles of the silicon nitride film relative to a base in a presence of the inhibition layer over the base forming the surface of the recess, and
the second number of incubation cycles is a number of incubation cycles of the silicon nitride film relative to the base in an absence of the inhibition layer over the base.
